(19) United States
(12) Patent Application Publication
(10) Pub. No.: US 2005/0199899 A1
(43) Pub. Date: Sep. 15, 2005

(54) Package array and package unit of flip chip LED

(76) Inventors: Ming-Der Lin, HsinChu City (TW); San-Bao Lin, Chuang Li City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/797,191

(22) Filed: Mar. 11, 2004

(51) Int. Cl. H01L 29/22

(52) U.S. Cl. 257/99

(57) ABSTRACT

A package array and its package unit of flip chip LED are proposed, wherein an LED chip is mounted on a ceramic material capable of enduing the eutectic temperature of the fabrication process for packaging. Next, metal wires are directly distributed on the ceramic material to finish an LED package unit, or a plurality of LEDs are serial/parallel connected with metal wires on the ceramic material to finish a high density package array. Because the ceramic material has a good thermal expansion match and a good thermal conductivity and the LED chip itself has a high reflective index match, the light emission characteristic and heat-radiating effect of the packaged LED can be effectively improved.

### FIELD OF THE INVENTION

The present invention relates to a package technique of flip chip LED and, more particularly, to a high density package array and its package unit of flip chip LED making use of a ceramic material having a good thermal expansion match.

### BACKGROUND OF THE INVENTION

The light emission principle of LED bases on inherent characteristics of semiconductor. Different from incandescence lamps, in an LED, light will be emitted when a current flows forwards into the PN junction of semiconductor. Therefore, LEDs are called cold lights. Because LEDs have the advantages of high durability, long lifetime, light weight, low power consumption and no noxious materials like mercury, they have been widely used in the illumination industry. Usually, LEDs are packaged in array to be used in electronic billboards and traffic signs.

A conventional LED package array comprises a plurality of LEDs, each LED having a chip mounted on a leadframe. A molding compound covers the chip and part of the leadframe to let metal pins of the leadframe be exposed out of the molding compound and used as external contacts. When assembled into an LED array, the metal pins of the LEDs are mounted onto metal wires of a printed circuit board to achieve electric connection between these LEDs. However, this kind of LED package array is restricted by the package size of the LED itself so that its volume can't be shrunk. Moreover, because the heat-radiating path of each LED is only the metal pin, the heat-radiating effect is much limited.

In another conventional LED package array, a plurality of LED chips are directly arranged on a printed circuit board for packaging. Speaking clearly, a metal wire layer corresponding to each LED is provided on the printed circuit board. The LED chips are directly mounted on the printed circuit board and achieve electric connection with the metal wire layer. Finally, a molding compound is used to cover each component on the printed circuit board to finish an LED package array. Although this kind of package array has a better packaging integration, its light emission efficiency and heat-radiating problem after packaging are still problems to be solved.

Accordingly, the present invention aims to propose a high density package array and its package unit of LED to effectively solve the problems in the prior art.

### SUMMARY AND OBJECTS OF THE PRESENT INVENTION

The primary object of the invention is to provide a package array and a package unit of flip chip LED, wherein a ceramic material having a good thermal expansion match is used for packaging. Metal wires are directly distributed on the ceramic material. A plurality of LEDs are then serial/parallel connected together to form a high density package array. Moreover, other electronic components like driving ICs or Schottky diodes can be used in the high density package array.

Another object of the invention is to provide a package array and a package unit of flip chip LED to enhance the packaging integration and effectively solve the heat-radiating problem after packaging.

Another object of the invention is to provide a flip chip LED package unit, which has a good thermal expansion match, a good thermal conductivity, and a high reflective index match.

Yet another object of the invention is to provide a package array and a package unit of flip chip LED to let one or more LED chips after packaged have a higher brightness and act as a uniform light source.

To achieve the above objects, an LED package array of the invention comprises a ceramic substrate made of a material capable of enduring the eutectic temperature of the fabrication process. Metal wires are then directly distributed on the ceramic substrate to form a metal wire layer. One or more LED chips are mounted on the metal wire layer on the surface of the ceramic substrate. These LED chips are electrically connected together through the metal wire layer to form a serial, parallel, or serial/parallel connected circuit.

According to another embodiment of the present invention, an LED package array comprises a metal body with a ceramic substrate provided thereon. The ceramic substrate is made of a material having a coefficient of thermal expansion matched with an LED chip. A conducting layer is formed on the ceramic substrate. An LED chip is mounted on the surface of the conducting layer on the ceramic substrate and achieves electric connection with the conducting layer. An external carrier substrate like a leadframe or a printed circuit board is also provided on the ceramic substrate. The LED chip achieves electric connection with the external carrier substrate through the conducting layer so that the external carrier substrate can be used as external conducting contacts. Finally, a lens is used to cover the LED chip to finish an LED package unit.

The various objects and advantages of the present invention will be more readily understood from the following detailed description when read in conjunction with the appended drawings, in which:

### BRIEF DESCRIPTION OF DRAWING:

FIG. 1 is a top view of a series/parallel connected package array of the present invention;

FIG. 2 is a diagram of a parallel connected package array of the present invention;

FIG. 3 is a diagram of a series connected package array of the present invention;

FIG. 4 is a cross-sectional view of a package array of the present invention; and

FIGS. 5 to 8 are diagrams of package units according to various embodiments of the present invention.

### DETAILED DESCRIPTION OF PREFERRED EMBODIMENT

In an LED chip, an LED epitaxy layer having a PN junction is formed on a GaN, sapphire, GaP or GaAs substrate, and two electrodes are electroplated at appropriate positions to provide an enough voltage difference between two ends of the epitaxy layer of the LED so that light can be generated in the PN junction on the epitaxy layer and then emitted out. In the invention, the LED chip is mounted on a ceramic material capable of enduring the eutectic temperature of the fabrication process for packaging. Metal wires are then directly distributed on the ceramic material to finish an LED package unit. Or a plurality of LEDs are serial/parallel connected together to finish a high density package array.

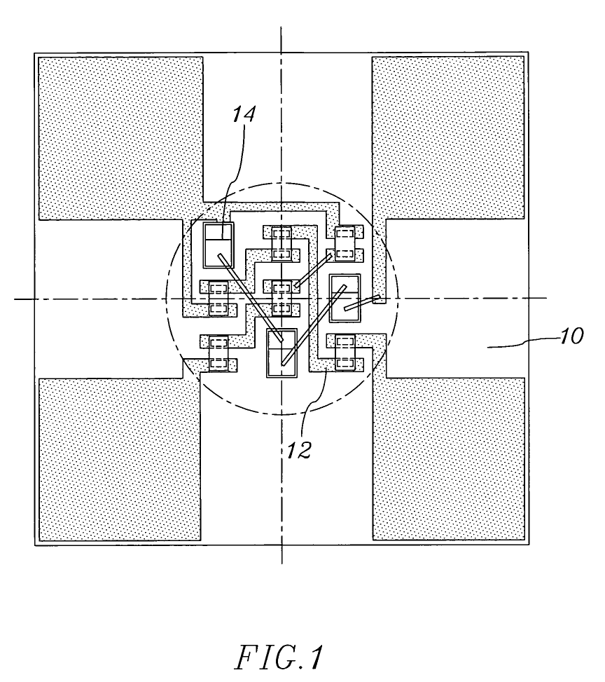

FIG. 1 shows a flip chip LED package array of the invention, wherein a metal wire layer 12 is distributed on the surface of a ceramic substrate 10. The ceramic substrate 10 is made of a material capable of enduring the eutectic temperature of the fabrication process and matching the coefficient of thermal expansion of an LED chip. The material of the ceramic substrate 10 can be AIN, Al₂O₃, BeO, SiC, ZrO₂ or glass ceramic. Several LED chips 14 are mounted on the ceramic substrate 10 by using a eutectic material like Au—Sn or Au—Si. The LED chips 14 are electrically connected together through the metal wire layer 12 to form a serial/parallel connected circuit. This packaging way can be designed to form a package array capable of emitting white light or an arbitrary light source.

A single LED chip can be mounted on the metal wire layer of the ceramic substrate to form a package unit, or several LED chips can be mounted on the metal wire layer of the ceramic substrate to form a package array. Moreover, other electronic components like driving ICs or Schottky diodes can be simultaneously matched on the metal wire layer of the ceramic substrate.

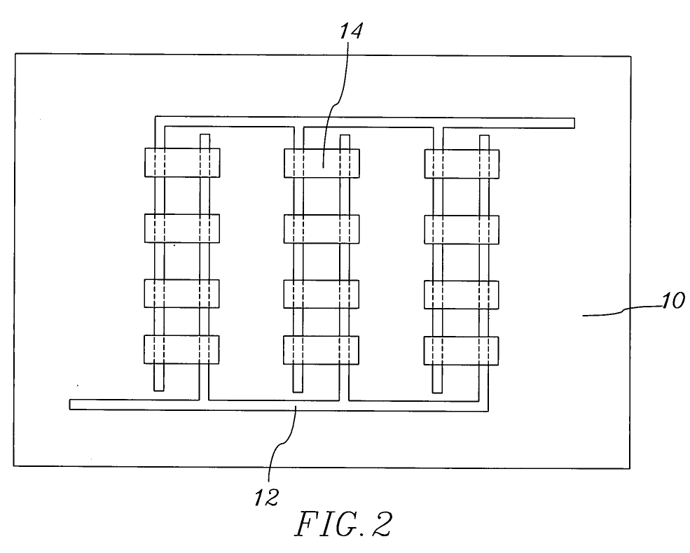

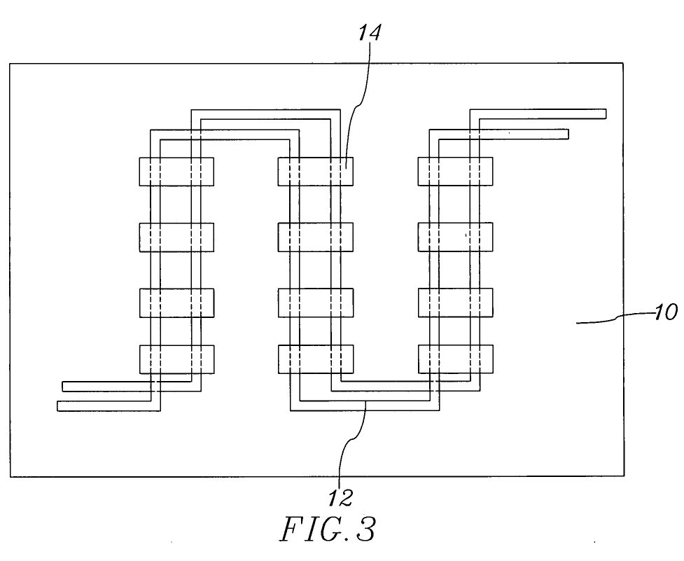

In addition to the above serial/parallel connected circuit, the present invention also provides a high current LED package array. As shown in FIG. 2, a plurality of LED chips 14 are parallel connected together by using a metal wire layer 12 on a ceramic substrate 10. As shown in FIG. 3, a high voltage LED package array can also be provided, wherein a plurality of LED chips 14 are mounted on a ceramic substrate 10, and the LED chips 14 are serial connected together by using the metal wire layer 12 to provide a high enough voltage.

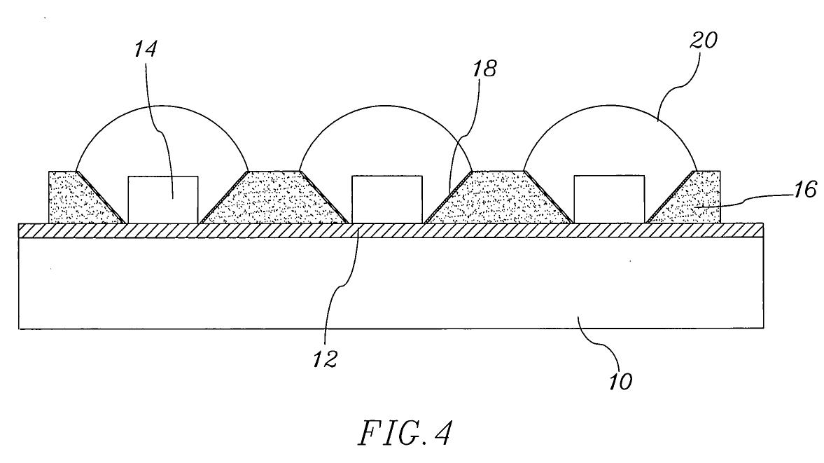

As shown in FIG. 4, a reflecting cover 16 can further be provided around each LED chip 14 or each set of LED chips 14 on the ceramic substrate 10. Each of the reflecting covers 16 has one or more LED chips 14 therein. A reflecting film 18 is formed on the inner surface of each of the reflecting covers 16. Finally, a lens 20 covers above each of the reflecting covers 16 so that light emitted by the LED chips 14 can be reflected many times in the reflecting cover 16 before emitted out of the lens 20, thereby letting the emitted light have a higher directionality and a higher brightness.

In the present invention, metal wires can be directly distributed on the ceramic substrate to serial/parallel connect several LEDs together for forming a high density LED package array, which has both the advantages of high uniformity and high packaging integration. Moreover, the present invention can make use of the characteristic of ceramic material to accomplish LED package units of different configurations, which will be illustrated below.

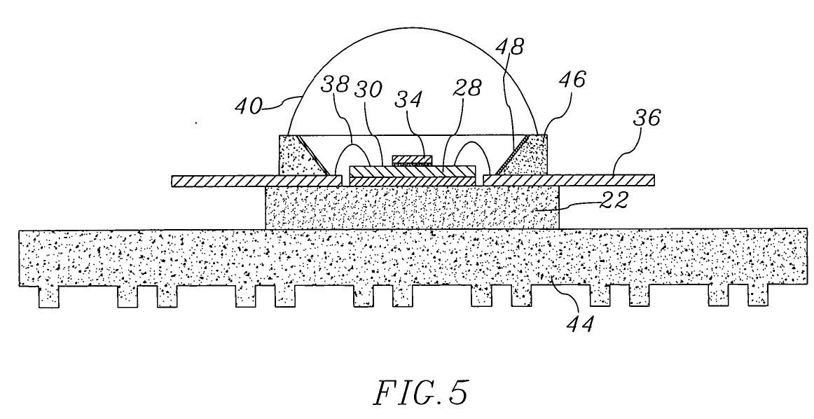

First, as shown in FIG. 5, a metal leadframe is used as an external carrier substrate of a flip chip LED package unit, wherein a ceramic substrate 28 is mounted on a metal body 22 of copper by using a thermally conductive adhesive 42, a solder paste or a eutectic material. The ceramic substrate 28 is made of a material matching the coefficient of thermal expansion of an LED chip 34, and is preferred to be AlN, Al₂o₃ or BeO. A conducting layer 30 is distributed on the upper surface of the ceramic substrate 28. The LED chip 34 is mounted on the surface of the conducting layer 30 on the ceramic substrate 28 by using a eutectic material 32 like Au—Sn or Au—Si formed by means of flip chip so that the LED 34 and the conducting layer 30 are electrically connected together. A leadframe 36 is mounted on the metal body 22 by means of sintering of glass or attach. A plurality of metal wires 38 are used to electrically connect the conducting layer 30 and the leadframe 36 so that the LED chip 34 can achieve electric connection with the leadframe 36 through the conducting layer 30 and use the leadframe 36 as external conducting contacts. Next, a reflecting cover 46 is annularly arranged on the leadframe 36 around the LED chip 34. A lens 40 is then directly mounted on the reflecting cover 46. A reflecting film 48 is formed on the inner surface of the reflecting cover 46. Light emitted by the LED chip 34 is reflected by the reflecting film 48 and then emitted out through the lens 40. The lens 40. above the metal body 22 covers components like the LED chip 34 and the wires 38. Because the eutectic material 32 used has a high thermal conductance, heat generated by the LED chip 34 can be quickly conducted out to enhance the heat-radiating effect. Besides, a metal heat-radiating fin 44 is further provided on the lower surface of the metal body 22. The material of the metal heat-radiating fin 44 has good electric and thermal conductivities (e.g., copper). The metal heat-radiating fin 44 has a larger area for radiating heat so that heat released by the LED chip 34 can be quickly radiated out.

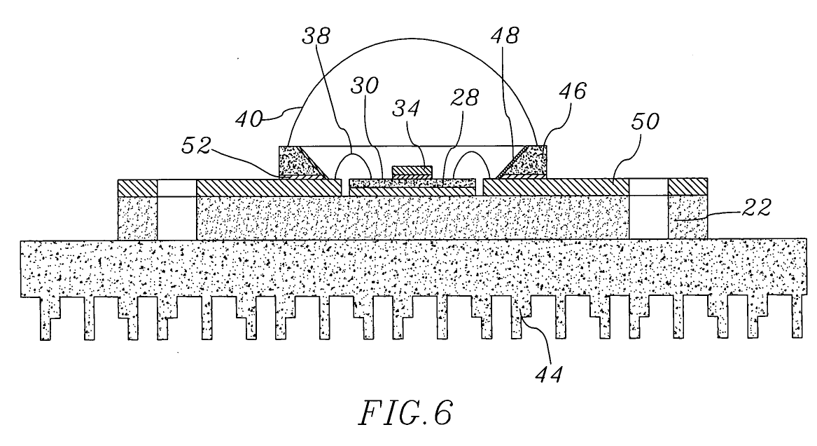

The leadframe 36 in FIG. 5 can be replaced with a printed circuit board 50, as shown in FIG. 6. A reflecting cover 46 is mounted on the printed circuit board 50 by using a non-conducting attach 52. Other structures are the same as in FIG. 5 and thus won't be further described.

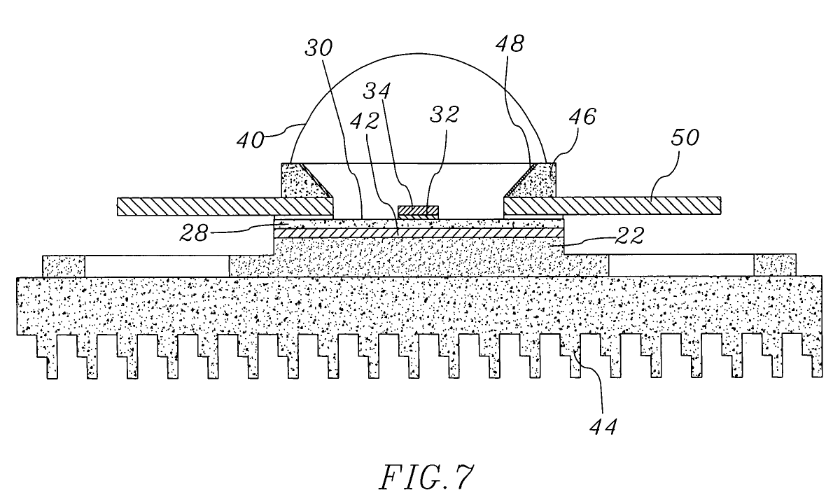

Besides, the printed circuit board 50 can be directly mounted on the ceramic substrate 28, as shown in FIG. 7, to let the printed circuit board 50 achieve electric connection with the conducting layer 30 on the ceramic substrate 28. It is not necessary to perform wire bonding. The LED chip 34 can achieve electric connection with the printed circuit board 50 through the conducting layer 30.

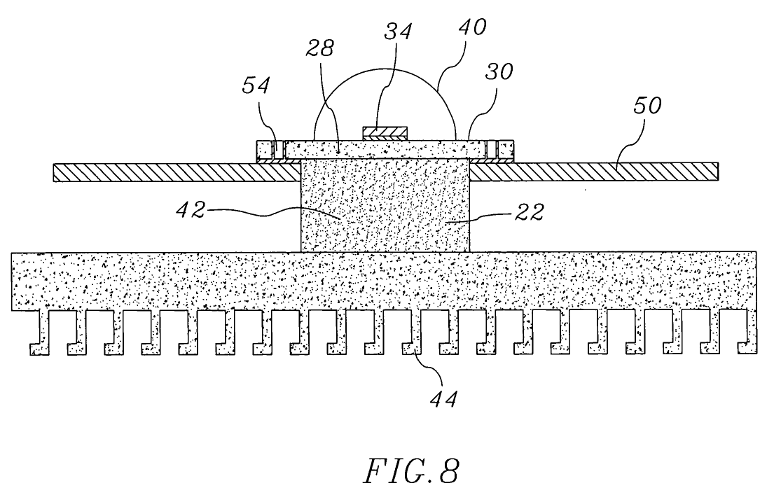

As shown in FIG. 8, the printed circuit board 50 is mounted on the lower surface of the ceramic substrate 28. Several through conducting plugs 54 are provided on the ceramic substrate 28. The conducting layer 30 on the ceramic substrate 28 achieves electric connection with the printed circuit board 50 by using the conducting plugs 54. The LED chip 34 is mounted on the conducting layer 30 of the ceramic substrate 28 by using the eutectic material 32, The lens 40 is then directly mounted on the ceramic substrate 28 to form an LED package unit.

To sum up, the present invention makes use of a ceramic material having a good thermal expansion match for packaging. Metal wires are directly distributed on the ceramic material to series/parallel connect a plurality of LEDs for forming a high density package array, hence increasing the packaging integration. Moreover, the good conductivity of the ceramic material is used to effectively solve the heat-radiating problem after packaging. Furthermore, the LED chip has a high reflective index match and thus can reduce total internal reflection. Therefore, the brightness of one or more LED chips packaged can be enhanced, and a uniform light source can be obtained.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defmed in the appended claims.

1. A flip chip LED package array comprising:
a ceramic substrate made of a material capable of enduring the eutectic temperature of the fabrication process;
a metal wire layer distributed on the surface of the ceramic substrate; and
one or more LED chips. mounted on the metal wire layer on the ceramic substrate, the LED chips being electrically connected together via the metal wire layer to form an electric circuit.

2. The flip chip LED package array as in claim 1, wherein one or more cavities are further formed in the ceramic substrate to accommodate at least one LED chip.

3. The flip chip LED package array as in claim 2, wherein a reflecting film is formed on the surface of each of the cavities.

4. The flip chip LED package array as in claim 1, wherein a reflecting cover is further annularly formed around each of the LED chips.

5. The flip chip LED package array as in claim 4, wherein the reflecting cover has one or more LED chips therein.

6. The flip chip LED package array as in claim 4, wherein a lens further covers the upper surface of the reflecting cover.

7. The flip chip LED package array as in claim 1, wherein the material of the ceramic substrate is selected from AlN, Al₂O₃, BeO, SiC, ZrO₂ and glass ceramic.

8. The flip chip LED package array as in claim 1, wherein the electric circuit is in one of the forms consisting of parallel, serial and serial/parallel connections.

9. The flip chip LED package array as in claim 1, wherein a. metal plate is further disposed on another surface of the ceramic substrate.

10. The flip chip LED package array as in claim 1, wherein the LEDs are mounted on the metal wire layer by using a eutectic substrate.

11. The flip chip LED package array as in claim 10, wherein the eutectic material is Au—Sn or Au—Si.

12. A flip chip LED package unit comprising:
a metal body;
a ceramic substrate mounted on the metal body, a conducting layer being distributed on the ceramic substrate;
an LED chip mounted on the surface of the conducting layer on the ceramic substrate to achieve electric connection, the ceramic substrate being made of a material having an coefficient of thermal expansion matched with the LED chip;
an external carrier substrate arranged on the metal body, the LED chip achieving electric connection with the external carrier substrate via the conducting layer as external conducting contacts, wherein the external carrier substrate is a printed circuit board or a metal leadframe; and
a lens covering said LED chip.

13. The flip chip LED package unit as in claim 12, wherein a reflecting cover is further annularly disposed on the external carrier substrate around the LED chip so that the lens can be mounted on the reflecting cover.

14. The flip chip LED package unit as in claim 13, wherein a reflecting film is formed on the inner surface of the reflecting cover.

15. The flip chip LED package unit as in claim 13, wherein the reflecting cover is mounted on the external carrier substrate by using a non-conducting attach.

16. The flip chip LED package unit as in claim 12, wherein the material of the ceramic substrate is selected from A1N, A1₂0₃, BeO, SiC, ZrO₂ and glass ceramic.

17. (canceled)

18. The flip chip LED package unit as in claim 12, wherein the metal leadframe can be mounted on the ceramic substrate by means of sintering.

19. The flip chip LED package unit as in claim 12, wherein the conducting layer on the ceramic substrate achieves electric connection with the external carrier substrate by using one or more metal wires.

20. The flip chip LED package unit as in claim 12, wherein the external carrier substrate is located at the lower surface of the ceramic substrate, and the external carrier substrate uses one or more conducting plugs to connect with the ceramic substrate.

21. The flip chip LED package unit as in claim 12, wherein a metal hear-radiating fin is further disposed on the lower surface of the ceramic substrate.

22. The flip chip LED package unit as in claim 12, wherein the LED chip is mounted on the conducting layer of the ceramic substrate by using a eutectic material.

23. The flip chip LED package unit as in claim 22, wherein the eutectic material is Au—Sn or Au—Si.

24. The flip chip LED package unit as in claim 12, wherein the ceramic substrate is mounted on the metal body by using a thermally conductive adhesive or solder.

25. The flip chip LED package unit as in claim 12, wherein the material of the metal body includes copper.

26. A flip chip LED package unit comprising:
a ceramic substrate made of a material capable of enduring the eutectic temperature of the fabrication process;
a metal wire layer distributed on the surface of the ceramic substrate;
at least an LED chip mounted on the conducting layer on the ceramic substrate to achieve electric connection.

27. The flip chip LED package unit as in claim 26, wherein one or more cavities are further formed in the ceramic substrate to accommodate the LED chip.

28. The flip chip LED package unit as in claim 27, wherein a reflecting film is formed on the surface of each of the cavities.

29. The flip chip LED package unit as in claim 26, wherein a reflecting cover is further annularly disposed around the LED chip.

30. The flip chip LED package unit as in claim 29, wherein a lens further covers the upper surface of the reflecting cover.

31. The flip chip LED package unit as in claim 26, wherein the material of the ceramic substrate is selected from AlN, Al₂O₃, BeO, SiC, ZrO₂ and glass ceramic.

32. The flip chip LED package unit as in claim 26, wherein a metal plate is further disposed on another surface of the ceramic substrate.

33. The flip chip LED package unit as in claim 26, wherein the LED chip is mounted on the metal wire layer by using a eutectic material.

34. The flip chip LED package unit as in claim 33, wherein the eutectic material is Au—Sn or Au—Si.
